(19) United States
(12) Patent Application Publication
(10) Pub. No.: US 2011/0089449 A1
(43) Pub. Date: Apr. 21, 2011

(54) LIGHT EMITTING DIODE PACKAGE STRUCTURE

(76) Inventors: He-Mu Chou, Taipei Hsien (TW); Hsiao-Chiao Li, Taipei Hsien (TW); Chung-Chuan Hsieh, Taipei Hsien (TW)

(21) Appl. No.: 12/778,144

(22) Filed: May 12, 2010

(30) Foreign Application Priority Data
Oct. 19, 2009 (TW) 098135252

(51) Int. Cl. H01L 33/00

(52) U.S. Cl. 257/98; 257/E33.056; 257/E33.068

(57) ABSTRACT

An LED package structure includes a house, an LED chip, a transparent cover, and a surrounding wall. The house has an upper surface, a cavity exposed by the upper surface, and a surrounding plane. The LED chip is disposed on the bottom surface of the cavity. The transparent cover is disposed on the surrounding plane and the opening of the cavity is sealed by the transparent cover. The surrounding wall is disposed on the upper surface of the house and surrounds the transparent cover.

### BACKGROUND OF THE INVENTION

1. Field of the Invention

The present invention is related to a light emitting diode (LED) package structure, and more particularly, to an LED package structure providing function of integration design of light path.

2. Description of the Prior Art

In daily life, use of projector has rapidly grown in popularity. For example, a projector may be used for presenting a report to make information offered by the report clearly understandable to every conferee in a conference. In addition, a projector may be used for projecting movie image at home such that the living room of home can provide enjoyment as a movie theater. With the improvement of technology, the major types of digital projectors comprise a cathode crystal tube (CRT) projector, a liquid crystal display (LCD) projector, a digital light processing (DLP) projector, and a liquid crystal on silicon (LCOS) projector. Every above-mentioned type of projectors needs a light source in its optical system. Conventionally, cold cathode fluorescent lamp (ccfl) and metal halide lamp are common used in a projector as its light source. However, the above-mentioned two types of light source have disadvantages of large volume, high power consumption, and lack of environment-friendly design. Compared with the above-mentioned traditional types of light sources, LED package components are smaller in size, lower in power consumption and environmental-friendly products, while having a better performance in brightness, colorfulness and a higher reaction speed to allow for high-frequency operation. As a result, those advantages described above make the LED packages more competitive in the market.

However, the technology of applying LED package device to a projector as its light source is not fully developed yet. General LED package device has a divergence angle of about 110 to 120 degrees and has no special mechanical design for being set in a projector, such that the light produced from the LED package device cannot be centralized effectively to precisely emit to the lens of the optical system of the projector, affecting the design of light path of the optical system of the projector and light utility. Therefore, it is still an important issue for the manufacturers to provide suitable LED package device for being light source of projectors.

### SUMMARY OF THE INVENTION

It is one of the objectives of the present invention to provide an LED package structure with special structural design such that the LED package structure of the present invention can be easily applied to a projector and the above-mentioned problem of light source of projectors can be solved.

According to the claimed invention, an LED package structure is provided. The LED package structure includes a house, an LED, a transparent cover, and a surrounding wall. The house has an upper surface and a cavity exposed by the upper surface, wherein the cavity has a bottom surface and an opening. The house further has a surrounding plane that surrounds the opening of the cavity. The LED is disposed on the bottom surface of the cavity. The transparent cover is disposed above the surrounding plane, and the opening of the cavity is sealed by the transparent cover. Furthermore, the surrounding wall is disposed above the upper surface of the house and surrounds the transparent cover.

It is an advantage that the LED package structure of the present invention does not include traditional sealant, such as epoxy, filled inside and covering the LED; therefore scattering of light produced by the LED and low reliability of the package structure caused from the sealant can be avoided. In addition, the LED package structure of the present invention further includes a surrounding wall disposed on its top surface for providing a function of positioning and locking the transparent cover such that the light produced by the LED can precisely emit along the light path of the design of the optical system of the projector so as to provide a preferable light utility.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of the topside outward appearance of an LED package structure according to a first embodiment of the present invention.

FIG. 2 is a schematic diagram of the sectional view of the LED package structure of the present invention shown in FIG. 1.

FIG. 3 is a schematic diagram of the downside outward appearance of the LED package structure of the present invention shown in FIG. 1.

FIG. 4 is a schematic diagram of the outward appearance of an LED package structure according to a second embodiment of the present invention.

FIG. 5 is a schematic diagram of the sectional view of the LED package structure of the present invention shown in FIG. 4.

### DETAILED DESCRIPTION

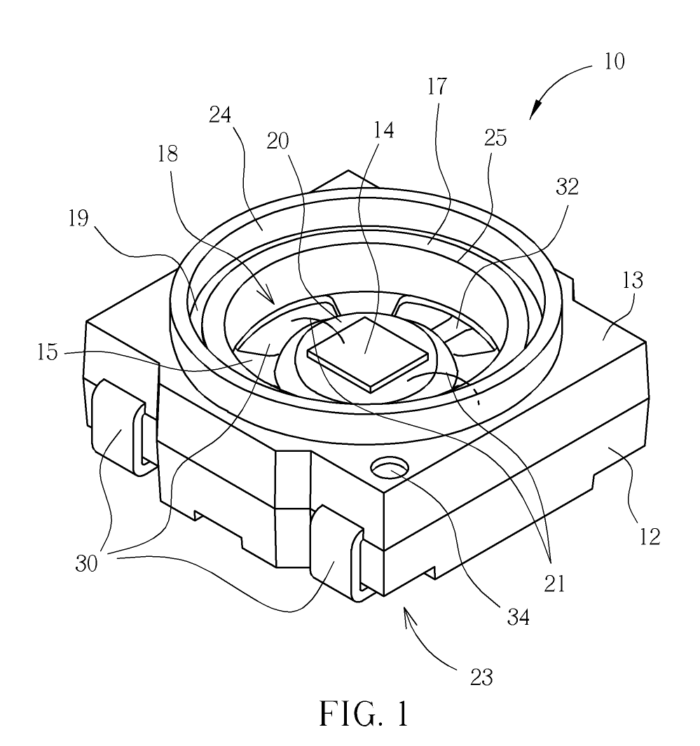

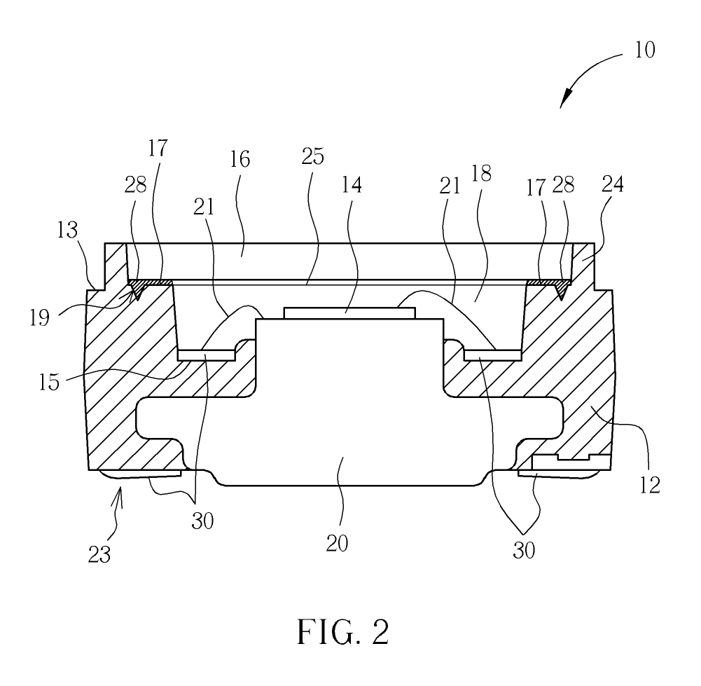

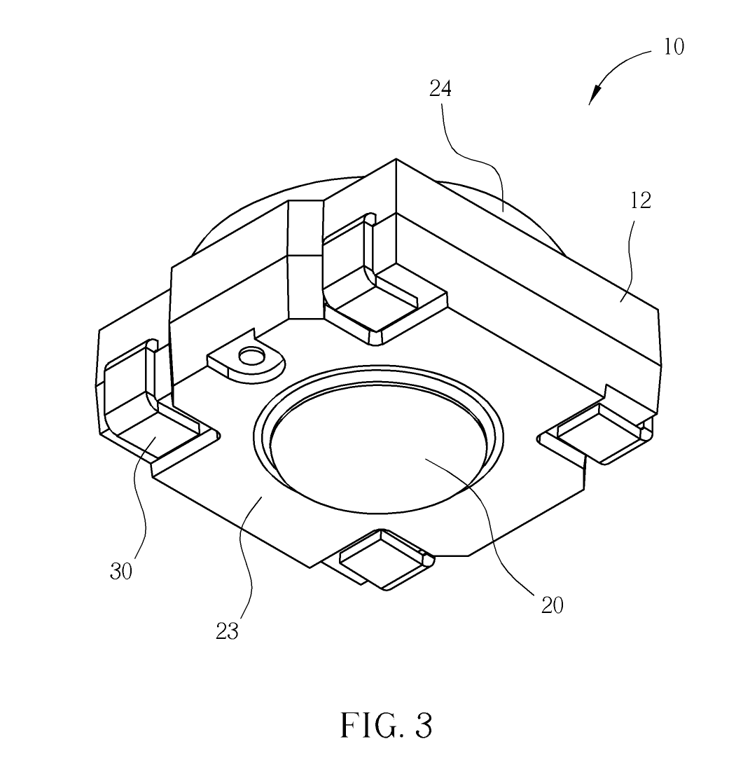

With reference to FIGS. 1-3, FIG. 1 and FIG. 3 are schematic diagrams of the topside outward appearance and downside outward appearance of an LED package structure according to a first embodiment of the present invention respectively, and FIG. 2 is a schematic diagram of the sectional view of the LED package structure shown in FIG. 1. The LED package structure 10 of the present invention can be applied to a projector for serving as a light source of the projector. The LED package structure 10 includes a package house 12, at least an LED chip 14, a transparent cover 16, and a heat dissipation device 20. The package house 12 has an upper surface 13 and a cavity 18. The cavity 18 is disposed in the package house 12 and exposed by the upper surface 13 of the package house 12. The cavity 18 has a bottom surface 15 and an opening 25. The heat dissipation device 20 is disposed on the bottom surface 15 of the cavity 18, extending downward and exposed by a lower surface 23 of the package house 12. The heat dissipation device 20 comprises materials with high thermal conductivity, such as metal materials. The heat dissipation device 20 has a flat top surface for positioning one or more LED chips with same or various sizes. In this embodiment, the LED chip 14 is disposed on the bottom surface 15 of the cavity 18 and is positioned in contact with the top surface of the heat dissipation device 20 directly. In addition, in this embodiment, the transparent cover 16 is a plate lens, such as a plate-type glass lens.

The LED package structure 10 further includes a surrounding wall 24 disposed on the upper surface 13 of the package house 12 for locking and positioning the transparent cover 16 therebetween. The LED package structure 10 even further includes a surrounding plane 17, disposed at the inner side of the surrounding wall 24. The surrounding plane 17 may be treated as a part of the package house 12. The surface of the surrounding plane 17 is used for supporting the fringe portion of the transparent cover 16 so that the transparent cover 16 is in contact with the inner sidewall of the surrounding wall 24 directly. In addition, an adhesive material 28, provided with dispensing method for example, may be disposed on the surface of the surrounding plane 17 for binding the fringe portion of the transparent cover 16 and the surface of the surrounding plane 17 so as to further fix the transparent cover 16 effectively. It should be noted that the package house 12 may further include a groove 19 disposed between the surrounding plane 17 and the surrounding wall 24 for containing the adhesive material 28 in order to further bind the transparent cover 16 and the surrounding plane 17. According to the design of the surrounding wall 24 and the surrounding plane 17, various types of lenses may be disposed at the inner side of the surrounding wall 24 provided that the size or shape of the fringe portion of the lens fits the shape of the surrounding wall 24. In this embodiment, the surrounding wall 24, the surrounding plane 17, and the package house 12 are monolithically formed, which means the LED package structure 10 includes a monolithically formed structure composed with the package house 12, the surrounding wall 24, and the surrounding plane 17, formed with plastic materials for example. This monolithically formed structure may be formed through an injection molding method. It should be noted that the space inside the cavity 18 and below the transparent cover 16 is not filled with any solid, encapsulation, or sealant materials. Only air or gas is filled inside the cavity 18, between the LED chip 14 and the transparent cover 16. However, in other embodiments, the space inside the cavity 18 may be a vacuum space, thus the cavity 18 is a vacuum cavity. Under this design, there is no encapsulation or traditional sealant materials disposed between the LED chip 14 and the transparent cover 16, such that light produced from the LED chip 14 can directly pass through the transparent cover 16 to emit out from the LED package structure 10. Therefore, LED package structure 10 does not have the disadvantage of emitting scattered light, easily degenerating, and high mist absorbency caused by filler of epoxy occurring in traditional LED package devices. Furthermore, the LED package structure of the present invention 10 has high ability of heat dissipation and good reliability.

Besides, the LED package structure 10 further includes at least a lead frame 30 enclosed with the package house 12. The LED chip 14 may be electrically connected to the lead frame 30 exposed by the cavity 18 through at least a lead 21. As shown in the figures, a portion of the lead frame 30 is disposed inside the cavity 18, another portion of the lead frame 30 is exposed on outside sidewalls of the package house 12 for electrically connecting an external circuit in order to provide power to the LED package structure 10. In other words, the bottom end of the lead frame 30 extends downward and is exposed with the lower surface 23 of the package house 12, and the top end of the lead frame 30 is exposed in the cavity 18. In other embodiment, the portion of the lead frame 30 exposed on the sidewalls of the package house 12 may be disposed on the bottom of the package house 12, but not limited by the illustration shown in FIG. 1. Furthermore, one or more voltage regulator devices, such as the zener diode 32, maybe disposed on the pad portion on the surface of the lead frame 30 in the cavity 18 or on the bottom surface 15 of the cavity 18 for further improving the stability of the LED package structure 10. In a preferable embodiment, the zener diode 32 is electrically connected to the LED chip 14 in parallel. In another aspect, a mark 34 may be disposed on the periphery part of the top side of the package house 12 for providing at least a function that users can easily recognize the position direction or model of the LED package structure 10.

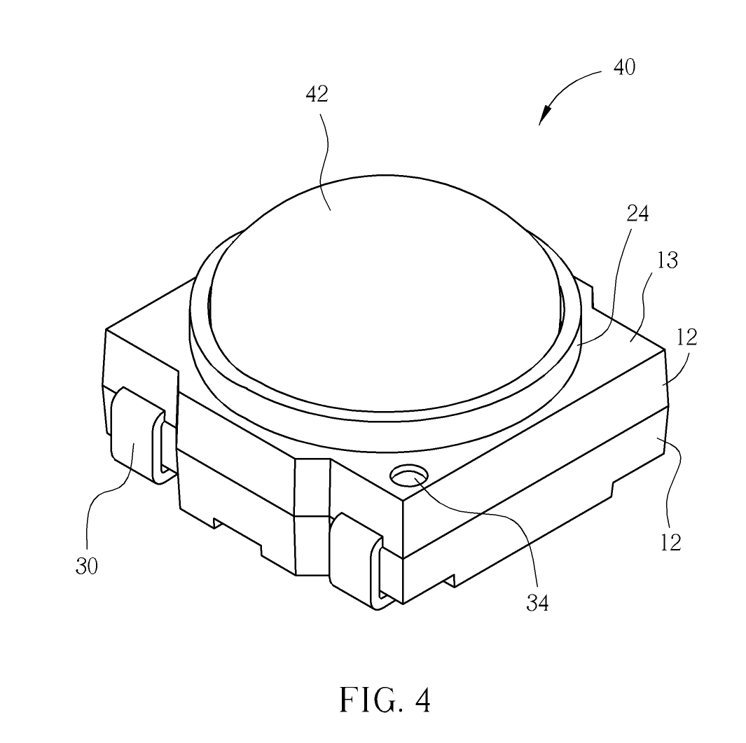

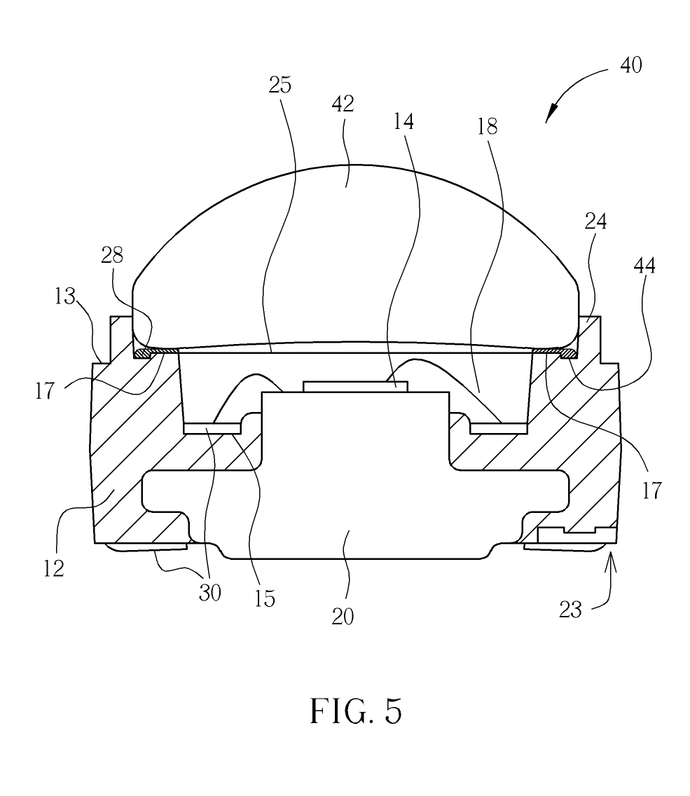

FIG. 4 and FIG. 5 are schematic diagrams of the outward and sectional vies of a second embodiment of the LED package structure of the present invention respectively; wherein the same numeral symbols are used for pointing out common devices of the first and the second embodiments. In this embodiment, the LED package structure 40 of the present invention may also be applied to a projector. The LED package structure 40 includes a package house 12, a heat dissipation device 20 disposed on the bottom surface 15 of the cavity 18, at least an LED chip 14 disposed on the upper surface of the heat dissipation device 20, and a transparent cover 42 disposed above the LED chip 14. The transparent cover 42 of this embodiment is a lens, preferably a convex lens. The transparent cover 42 is capable of concentrating the light produced by the LED chip 14 to emit outward. For example, the transparent cover 42 enables the light to emit linearly in perpendicular to the upper surface 13 of the package house 12 out of the LED package structure 40, such that the light can align the optic axis design of the optical system of projector. The LED package structure 40 of the present invention further includes a surrounding wall 24 disposed on the upper surface of the package house 12 for locking and positioning the transparent cover 42. A surrounding plane 17 is disposed at an inner side of the surrounding wall 24 for positioning and supporting the fringe portion of the transparent cover 42. In addition, a groove 44 is disposed between the surrounding plane 17 and the surrounding wall 24, below the surrounding plane 17. In this embodiment, an adhesive material 28 may be coated or filled on the surrounding plane 17 and in the groove 44 for binding the surrounding plane 17 and the fringe portion of the transparent cover 42 to effectively fix the fringe portion of the transparent cover 42 inside the surrounding wall 24. In preferable embodiments, the package house 12, the surrounding wall 24, the surrounding plane 17, and the groove 44 are designed as a monolithically formed structure. Furthermore, the upper surface of the package house 12 may include a mark 34 such that users can recognize the position direction and model or type of the LED package structure 40. Similar to the previous embodiment, there is no package sealant material or encapsulation (such as epoxy) used in traditional package structures filled between the LED chip 14 and the transparent cover 42. In other words, only air or gas is filled in the cavity 18. Alternatively, the cavity 18 is a vacuum cavity.

In contrast to the prior art, it is an advantage of the LED package structure of the present invention that no package sealant materials or encapsulation, such as epoxy, of traditional package structures is filled in the LED package structure, such that the disadvantages of LED package structure of prior arts of high mist absorbency, high degeneration, bad dissipation, and high light scattering can be effectively avoided. In other words, only gas is filled between the transparent cover (such as lens) and LED chip, or the cavity is a vacuum between the transparent cover and the LED chip of the LED package structure of the present invention. Since no any other solid, sealant, or encapsulation material is filled between the LED chip and the transparent or inside the cavity, the light produced by the LED chip directly emits upward through the lens or the transparent cover positioned above the LED chip so as to effectively align the light path design in company with the design of the type of lens. Furthermore, because there is no sealant material filled in the cavity, the LED package structure of the present invention has high reliability and good heat dissipation. In addition, the surrounding wall is capable of effectively fixing the transparent cover inside to provide fixing and positioning function and enable the light emit from the LED package structure to align a predetermined light axis of any optical system. For example, according to the design of the optical system and mechanism design of a projector, the mechanism of the projector can directly fix the position of the surrounding wall such that the light produced from the LED package structure can effectively align the light axis of the optical system of the projector without deviation. In another aspect, the surrounding wall may contain various types of lens or other transparent cover for designing the light path for guiding light to a specific direction, in order to provide the required incident light path of the projector and to effectively improve the light utility. As a result, the LED package structure of the present invention can be finely applied to the optical system of the projector to raise the use efficiency of the light source, and therefore the total volume of the projector can be reduced to meet the market requirement. Accordingly, the projector adopting the LED package structure of the present invention can be further applied to portable information productions.

Those skilled in the art will readily observe that numerous modifications and alterations of the device and method may be made while retaining the teachings of the invention.

What is claimed is:

1. A light emitting diode (LED) package structure, comprising:
a house having an upper surface and a cavity disposed on the upper surface, the cavity having a bottom surface and an opening, the house further having a surrounding plane surrounds the opening of the cavity;
an LED disposed on the bottom surface of the cavity;
a transparent cover disposed above the surrounding plane, the opening of the cavity being sealed by the transparent cover; and
a surrounding wall disposed above the upper surface of the house and surrounding the transparent cover.

2. The LED package structure of claim 1, further comprising an adhesive material disposed on the surrounding plane for binding the surrounding plane and the transparent cover.

3. The LED package structure of claim 1, wherein the house further comprises a groove disposed between the surrounding plane and the surrounding wall.

4. The LED package structure of claim 3, further comprising an adhesive material disposed in the groove for binding the house and the transparent cover.

5. The LED package structure of claim 1, further comprising a heat dissipation device disposed on the bottom surface of the cavity, the heat dissipation device extending downward and being exposed by a lower surface of the house, and the LED being disposed on a surface of the heat dissipation device.

6. The LED package structure of claim 1, wherein the cavity is a vacuum cavity or the cavity is filled with air.

7. The LED package structure of claim 1, comprising a monolithically formed structure which is composed with the house and the surrounding wall.

8. The LED package structure of claim 1, further comprising at least a lead frame enclosed with the house, a bottom end of the lead frame extending downward and being exposed by a lower surface of the house, and an top end of the lead frame being exposed in the cavity.

9. The LED package structure of claim 1, further comprising a zener diode disposed on the bottom surface of the cavity and electrically connected to the LED.

10. The LED package structure of claim 9, wherein the zener diode and the LED are electrically connected in parallel.

11. The LED package structure of claim 1, wherein the transparent cover is a plate lens or a convex lens.

12. The LED package structure of claim 8, wherein the LED is electrically connected to the lead frame exposed in the cavity through at least a lead.
